(19) United States
(12) Patent Application Publication
(10) Pub. No.: US 2007/0195611 A1
(43) Pub. Date: Aug. 23, 2007

(54) Programmable structure, a memory, a display and a method for reading data from a memory cell

(76) Inventors: Ralf Symanczyk, Tuntenhausen (DE); Cay-Uwe Pinnow, Munchen (DE)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/360,149

(22) Filed: Feb. 23, 2006

(51) Int. Cl. G11C 7/10

(52) U.S. Cl. 365/189.01

(57) ABSTRACT

The invention refers to an improved programmable structure, an improved memory, an improved display and an improved method for reading data from a memory cell. More particularly, embodiments of the invention provide a programmable structure and a memory, whereby a programmed state of the programmable structure and a programmed state of a memory cell of the memory can be read out with a simple method. According a further aspect of the present invention, the stored data of the programmable structure and the stored data of the memory device can be read out according an improved method. In accordance with one exemplary embodiment of the present invention, a programmable structure comprises an ion conductor layer, a modifying device coupled to the ion conductor layer, the modifying device being operable to change an electromagnetic property of the ion conductor layer, an emitting device for sending an electromagnetic radiation to the ion conductor layer and a receiving device for receiving an electromagnetic radiation from the ion conductor layer. The ion conductor layer is configured that when a bias is applied across the ion conductor layer an electromagnetic property of the ion conductor layer is changed. Therefore it is possible to program different states referring to different electromagnetic properties of the ion conductor layers. The different states of the ion conductor layer can be read by sending an electromagnetic radiation to the ion conductor layer and receiving the electromagnetic radiation from the ion conductor layer.

### BACKGROUND OF THE INVENTION

1. Field of the Invention

Embodiments of the present invention refer to a programmable structure, memory and display. Furthermore embodiments of the present invention relate to a method for reading data from a memory cell.

2. Description of the Related Art

Memory cells comprising a solid electrolyte material are well known as programmable metallization memory cells (PMC memory cells). Memory devices including such PMC memory cells are known as conductive bridging random access memory devices (CBRAM). The storing of different states in a PMC memory cell is based on the development or diminishing of a conductive path in the electrolyte material between electrodes based on an applied electric field. Although the electrolyte material may typically have a high resistance, the conductive path between electrodes may be adjusted to lower resistance. Thus, the PMC memory cell may be set to different states depending on the resistance of the PMC memory cell. Typically, both states of the PMC memory cell are sufficiently time-stable in such a way that data may permanently be stored.

A PMC memory cell is typically operated by applying a positive or a negative voltage to the solid electrolyte of a PMC memory element. To store data into the PMC memory cell, the PMC memory cell is brought to a program state by applying a suitable programming voltage to the PMC memory cell which results in the creation of the conductive path in the electrolyte material and which may correspond to the setting of a first state with low resistance. In order to store a second state in the PMC memory cell with high resistance, an erase voltage may be supplied in such a manner that the resistance of the PMC memory cell changes back to a high resistance which may correspond to second state with a high resistance (e.g. an erased state). To read the PMC memory cell, a read voltage may be applied which may be lower than the programming voltage. With the read voltage, a current through the resistance of the PMC memory element may be detected and associated to the respective low or high resistance state of the PMC memory cell. The electrolyte material constitutes an ion conductor layer that is used for programming different states.

What is needed are an improved programmable structure for storing data, an improved memory with an ion conductor layer and an improved display with an ion conductor layer. Additionally, there is a need for an improved method for reading data from a memory cell with an ion conductor layer.

### SUMMARY OF THE INVENTION

Embodiments of the present invention provide an improved programmable structure, an improved memory, an improved display and an improved method for reading data from a memory cell. More particularly, embodiments of the invention provide a programmable structure and a memory, whereby a programmed state of the programmable structure and a programmed state of a memory cell of the memory can be read out with a simple method. According a further aspect of the present invention, the stored data of the programmable structure and the stored data of the memory device can be read out according to an improved method.

In accordance with one exemplary embodiment of the present invention, a programmable structure comprises an ion conductor layer, a modifying device coupled to the ion conductor layer, the modifying device being operable to change an electromagnetic property of the ion conductor layer, an emitting device for sending an electromagnetic radiation to the ion conductor layer and a receiving device for receiving an electromagnetic radiation from the ion conductor layer. The ion conductor layer changes its electromagnetic property when a bias is applied across the ion conductor layer. Therefore it is possible to program different states referring to different electromagnetic properties of the ion conductor layer. The different states of the ion conductor layer can be read by sending an electromagnetic radiation to the ion conductor layer and receiving the electromagnetic radiation from the ion conductor layer.

In accordance with a further aspect of this embodiment, the electromagnetic property of the ion conductor layer may be changed by an amount of energy used to program the device. The energy may be applied to the ion conductor layer by a bias.

In accordance with an embodiment that uses a bias for modifying a programmed state of the ion conductor layer, the programmable structure comprises a first and a second electrode, whereby the ion conductor layer is arranged between the first and the second electrode, whereby the first electrode comprising dissolvable ions. Additionally according to this embodiment, a voltage source is arranged as a modifying device that is connected with the first and the second electrode, whereby the voltage source is operable to apply a voltage higher than a threshold voltage to the first and the second electrode to dissolve ions from the first electrode and carrying the dissolved ions in the ion conductor layer, whereby the dissolving of the ions changes an electromagnetic property of the anode. Therefore, according to this embodiment, the changed programmed state can be checked by sending an electromagnetic radiation to the first electrode and sensing a reflected electromagnetic radiation of the first electrode.

In accordance with a further exemplary embodiment of the invention, a programmable structure comprises a memory cell with a first and a second electrode and an ion conductor layer between the first and the second electrode. The electromagnetic property of the ion conductor layer is changeable for storing different data in the memory cell. In this embodiment an evaluating device is provided for deciding on a signal generated by the detecting device on the basis of a received electromagnetic radiation whether the memory cell is in the first state.

In accordance with another embodiment of the invention, a memory is provided with at least one memory cell with a first and a second electrode and an ion conductor layer between the first and the second electrode. The memory comprises a controllable voltage source connected with the memory cell operable for applying a voltage on the first and the second electrode to solve ions with the first electrode in the ion conductor layer. Additionally, the memory comprises an emitting device for sending an electromagnetic radiation to the memory cell. Furthermore, the memory comprises a detecting device for receiving electromagnetic radiation received from the memory cell. And the memory comprises an evaluating device for deciding on a signal generated by the detecting device whether the memory cell is in a first programmed state.

In accordance with another embodiment of the invention, a display is provided with an ion conductor layer, a modifying device coupled to the ion conductor layer, the modifying device being operable to change an electromagnetic property of the ion conductor layer, an emitting device for sending an electromagnetic radiation to the ion conductor layer, a receiving device for receiving an electromagnetic radiation that is emitted from the ion conductor layer, the receiving device being at least part of the display, the display showing different optical information depending on the programmed state of the ion conductor layer.

In accordance with another embodiment of the invention, a method for storing data in a memory cell is provided, whereby the memory cell comprises a first and a second electrode and a programmable ion conductor layer arranged between the first and the second electrode. The first electrode comprises solvable ions. A data is stored in the memory cell by applying an energy on the memory cell for dissolving ions of the first electrode and carrying the ions in the ion conductor layer. Therefore the electromagnetic property of the memory cell is changed. The data can be read out by sending an electromagnetic radiation to the memory cell, receiving an electromagnetic radiation from the memory cell and detecting a first state depending on the received electromagnetic radiation. In accordance with one aspect of this embodiment, the energy is supplied by a bias that dissolves ions from the first electrode in the ion conductor layer. In accordance with a further aspect of this embodiment, a programmed state is detected if a radiation efficiency of the received electromagnetic radiation is higher than a predetermined value. In accordance with a further aspect of this embodiment, a first state of the memory cell corresponding to a first data is detected if a spectrum of the received electromagnetic radiation equals a predetermined electromagnetic radiation spectrum.

### BRIEF DESCRIPTION OF THE DRAWINGS

A more complete understanding of the present invention may be derived by referring to the detailed description and claims, considering in connection with the Figures, wherein like reference numbers refer to similar elements throughout the Figures, and:

FIG. 1 depicts a programmable structure with an ion conductor layer;

FIG. 2 depicts a schematic diagram of current and bias voltage for writing and erasing a data in a programmable structure.

FIG. 3 depicts an embodiment with a programmable structure, a emitting and a detecting device using reflected radiation for detecting different programmed states.

FIG. 4 depicts a schematic view of an embodiment with a programmable structure, an emitting and a detecting device using transmitted radiation for detecting different programmed states of the programmable structures;

FIG. 5 depicts a partial view of a memory with a memory element and a reading circuit for reading the programmed state of the memory element;

FIG. 6 depicts a schematic view of an embodiment of a programmable structure;

FIG. 7 depicts an embodiment with an array of programmable structures and an array of detecting devices;

FIG. 8 depicts a schematic view of a further embodiment with a substrate with an array of programmable structures and a second substrate with an array of emitting and detecting devices.

FIG. 9 depicts a schematic view of a display with an array of programmable structures

Skilled artisans will appreciate that elements in the Figures are illustrated for simplicity and clarity and have not necessarily being drawn to scale. For example, the dimensions of some of the elements and the Figures may be exaggerated relative to other elements to help to improve understanding of embodiments of the present invention.

### DETAILED DESCRIPTION OF THE PREFERRED EMBODIMENT

The embodiments of the present invention may be described in terms of various functional components. It should be appreciated that such functional components may be realized by any number of hardware and structural components configured to perform these specified functions.

One embodiment of the invention provides a programmable structure comprising an ion conductor layer, a modifying device, the modifying device being operable to change an electromagnetic property of the ion conductor layer, an emitting device for sending an electromagnetic radiation to the ion conductor layer, and a receiving device for receiving an electromagnetic radiation from the ion conductor layer.

Another embodiment of the invention provides a programmable structure comprising an ion conductor layer that can be programmed easily and the programmed state can be read out by detecting electromagnetic property of the ion conductor layer that is different in the two programmable states. Embodiments of the present invention also provide a memory comprising a memory cell with a first and a second electrode and an ion conductor layer between the first and the second electrode, whereby electromagnetic property of the ion conductor layer can be changed permanently and two different programming states can be detected by sensing two different electromagnetic properties of the memory cell. Therefore it is not necessary to apply a voltage on the memory cell for detecting the programming state. The electromagnetic property of the memory cell may be checked using an electromagnetic radiation that is sent to the memory cell. For detecting the different states of the electromagnetic property of the memory cell a reflectivity of the memory cell or a damping property of the memory cell for the electromagnetic radiation is used. Depending on the programming state of the memory cell, more or less electromagnetic radiation is reflected or dampened by the memory cell.

A further embodiment of the present invention provides a display comprising an ion conductor layer, whereby the ion conductor layer may be programmed in two different states, whereby the different states of the ion conductor layer result in different electromagnetic properties of the ion conductor layer. The different states of the ion conductor layers may result in different reflectivity of the ion conductor layer or the first electrode after dissolving ions from the first electrode. According to a further embodiment the different electromagnetic properties of the ion conductor layers are checked by comparing a dampening property of the ion conductor layer for electromagnetic radiation. Depending on the different programming state, the ion conductor layer transmits or reflects an electromagnetic radiation with a different electromagnetic spectrum or a different luminance. Therefore an array of ion conductor layers may be programmed for displaying optical information on the display.

Furthermore, one embodiment of the present invention provides a method for reading data from a memory cell with a first and a second electrode and a programmable ion conductor layer arranged between the first and the second electrode. The first electrode comprising solvable ions. Data may be stored in the memory cell by applying a signal to the memory cell for dissolving ions of the first electrode and carrying the ions in the ion conductor layer. The dissolving of the ions and the carrying of the ions in the ion conductor layer changes the electromagnetic property of the memory cell. Therefore the different programmed states can be read out by checking the electromagnetic property of the memory cell. In example the electromagnetic property of the memory cell may be sensed by sending electromagnetic radiation to the memory cell and receiving an electromagnetic radiation from the memory cell. The different programmed states may be determined by comparing the reflectivity with a predetermined reflectivity or comparing an absorbing property for the electromagnetic radiation by the memory cell. In a further embodiment, the reflected or transmitted luminance or the reflected or transmitted spectrum of the electromagnetic radiation may be checked and compared with predetermined values.

One embodiment of the present invention may be described in terms of various functional components. Such functional components may be realized by any number of hardware or structural components configured to perform the specified functions. For example, one embodiment of the present invention may employ various integrated components comprised of various electrical devices, for example, resistors, transistors, capacitors, diodes and the like, the values of which may be configured for various intended purposes. Embodiments of the present invention may be practiced in any integrated circuit application where a programmed state may be detected by checking an electromagnetic property. While various components may be coupled or connected to other components within exemplary circuits, such connections and couplings can be realized by direct connection between components and by connection through other components and devices located in between.

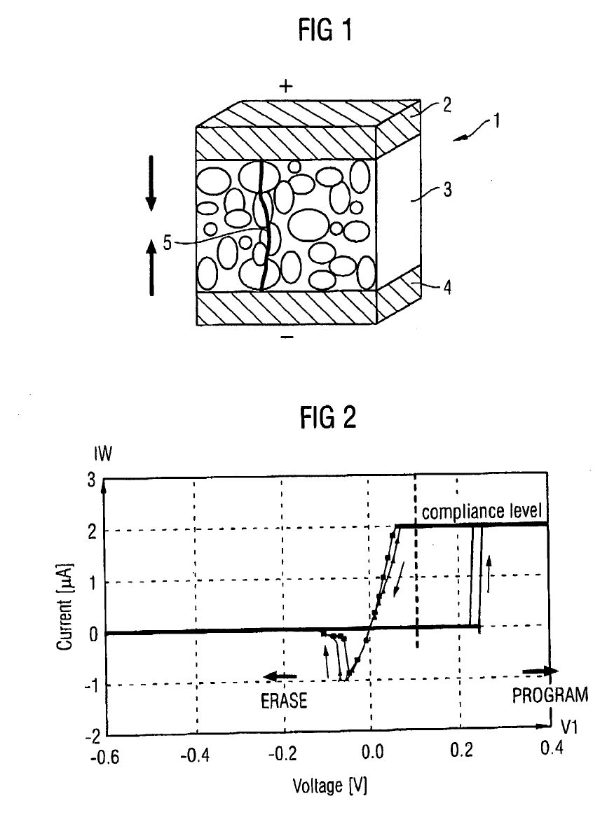

FIG. 1 depicts an embodiment of a programmable structure 1 including a first electrode 2, a second electrode 4 and an ion conductor layer 3. The first electrode 2 may comprise solvable ions and may be connected in one embodiment to a high potential, for example, during a programmable operation. The second electrode 4 may be connected in this embodiment to a ground potential that is lower than the high potential. In this embodiment, the first electrode 2 functions as an anode and the second electrode 4 functions as a cathode. The programmable structure 1 may be used for store information and thus may be used in memory circuits. For example, in one embodiment, a programmable structure may be used in memory devices to replace DRAM, SRAM, PROM, EEPROM, flash devices or any combination of such memories. In addition, in one embodiment, programmable structures described herein may be used for other applications where programming or changing of electromagnetic properties of a portion of an electrical circuit in example a display are desired.

In one embodiment, the ion conductor layer 3 may be formed by material which conducts ions upon application of a sufficient high voltage. Suitable materials for ion conductors include polymers, glasses and semiconductor materials. In one exemplary embodiment of the invention, the ion conductor layer may be formed by chalcogenide material, i.e. sulfide or selenid. The chalcogenide may comprise compounds of sulfur, selenium and tellurium such as GeSe. AsS, GeAsTe, AlGeAsTe, GeTeSb among others in various compositions. The ion conductor layer 3 may also include dissolved and/or dispersed conductive material. For example, the ion conductor layer may comprise a solid solution that includes dissolved metals and/or metal ions. Chalcogenide material including silver, copper, combinations of these materials, and the like may be used for the ion conductor layer.

In one embodiment, the first electrode 2 and the second electrode 4 may be formed by any suitable conductive material. For example, the fist electrode 2 and the second electrode 4 may be formed by doped polysilicon material or metal. In one embodiment of the present invention, one of the electrodes, in example the first electrode 2 may be formed by a material including a metal which dissolves in ion conductors when a sufficient bias is applied across the electrodes and the second electrode, in example the cathode may be relatively inert and may not be dissolved during operation of the programmable structure.

The first electrode 2 may be an anode during a write operation changing the electromagnetic property of the programmable structure permanently from a first to a second state. The first electrode 2 may be comprised of a material including silver which dissolves in the ion conductor layer 3. The second electrode 4 may be a cathode during the write operation and be comprised of an inert material such as tungsten, nickel, molybdenum, platinum, metal silicides, and the like.

In one embodiment, the programmable structure may be configured in such a way that when a bias larger than a threshold voltage is applied across the electrodes 2, 4, the electromagnetic properties of the ion conductor layer and/or the first anode 2 are changed. For example, if a voltage is applied larger than a threshold voltage, conductive ions within the ion conductor layer may start to migrate to form at least a region having a changed reflectivity for an electromagnetic radiation. In a further embodiment, if a voltage is applied larger than the threshold voltage, conductive ions within the ion conductor layer may start to migrate to form at least a region having a reduced reflectivity for electromagnetic radiation. In a further embodiment, by applying an energy to the programmable structure the electromagnetic property of the first electrode 2 and/or the ion conductor layer are changed. For example by applying a sufficient high energy ions of the first electrode may be dissolved in the ion conductor layer.

In the basic reaction, if a high voltage is applied to the first electrode, a redox reaction at the second electrode 4 may drive metal ions from the reactive first electrode into the ion conductor layer 3. Therefore, in the ion conductor layer 3, metal-rich clusters may be formed. The result may be a conductive bridge that occurs between and the first and the second electrode 2, 4. Additionally, because of the dissolving of ions from the first electrode 2, electromagnetic property of the first electrode 2, electromagnetic property of an interface between the first electrode 2 and the ion conductor layer 3 and electromagnetic property of the ion conductor layer 3 may be changed by dissolving the metal. If a reverse voltage is applied to the programmable structure 1, the metal-rich clusters may be dissolved and the conductive areas with a conductive bridge may be degraded, thereby increasing the resistance of the programmable structure 1 and changing electromagnetic properties of the first electrode 2, electromagnetic property of the interface between the first electrode 2 and the ion conductor layer 3 and the electromagnetic properties of the ion conductor layer 3. Therefore the programmable structure 1 comprises the same electromagnetic properties as before the programming process. It is possible to detect the programming state of the programmable structure 1 by checking the electromagnetic properties of the programmable structure 1. Depending on the used materials and the used electromagnetic radiation, a reflectivity of the programmable structure 1 especially of the first electrode 2 may be decreased by dissolving ions in the ion conductor layer 3. In another embodiment the dampening property for electromagnetic radiation is decreased by dissolving ions from the first electrode in the ion conductor layer 3.

FIG. 1 depicts the programmable structure 1 with the first and the second electrode 2, 4. In the depicted state, a metal-rich cluster 5 is generated in the ion conductor layer 3 that builds a conductive bridge between the first and the second electrode 2, 4. However, as explained above, it is not necessary for changing the electromagnetic property of the first electrode 2 or of the ion conductor layer that a whole conductive bridge is generated. It may be sufficient to solve a predetermined amount of metallic ions from the first electrode 2 and dissolve the ions in the ion conductor layer 3.

FIG. 2 shows a diagram of the voltage and the current occurring during a programming operation, an electrical read operation and an erase operation of the programmable structure 1, according to one embodiment of the invention. Initially, the programmable structure 1 may not programmed and may therefore have a high resistance and a predetermined reflectivity for electromagnetic radiation. In another embodiment, the programmable structure may have a predetermined absorbing behavior for electromagnetic radiation. In a further embodiment, the programmable structure may have a predetermined reflectivity and/or absorbing behavior for a predetermined spectrum of an electromagnetic radiation.

If a voltage is applied with a higher potential at the first electrode 2 and a lower potential at the second electrode 4, no current may flow through the programmable structure 1 until a threshold voltage (VI, or programming voltage) is applied. The electromagnetic properties of the programmable structure may not be changed until a threshold voltage is applied. When the applied voltage rises over the threshold voltage VI, current may flow until a working current IW is achieved and may be confined (in example limited) by a programming circuit. The current is generated by dissolving ions in the ion conductor layer that changes the electromagnetic properties of the programmable structure 1 for electromagnetic radiation.

In one embodiment, the voltage may then be reduced to zero Volts, whereby the current falls to zero Ampere, thereby completing the programming of the programmable structure 1.

In one embodiment, to erase the program status of the programmable structure 1, a lower voltage, e.g. a negative voltage (also referred to as an erasing voltage) may be applied to the first electrode 2. The negative voltage may be about −0.1 V in one embodiment. When the erasing voltage is applied to the programmable structure 1, a negative current may flow through the programmable structure 1. When the negative voltage drops to below −0.1 V, the current may stop flowing (in example, decrease to 0 A). After the erasing voltage has been applied to the programmable structure 1, the programmable structure 1 may have the same electromagnetic property as prior to the programming operation, thereby erasing the values stored in the programmable structure 1. According to this simple explanation of the invention it is understood that a principle of the invention is to use an electromagnetic radiation for sensing or reading a programmed state of the programmable structure 1. In the explained embodiments, a voltage is applied to change the electromagnetic property of the programmable structure 1. In another embodiment, instead of using a voltage for programming and/or for erasing the program status of the programmable structure 1, also an another method may be used, in example applying a high temperature and/or electromagnetic radiation with a high energy to change the electromagnetic property of the programmable structure 1.

If the program state of the programmable structure 1 is to be sensed or read, an electromagnetic radiation may be applied to the programmable structure 1. The electromagnetic radiation may be in the visible range, in the ultraviolet range or in the infrared range. The electromagnetic radiation may be applied to the surface of the first electrode 2.

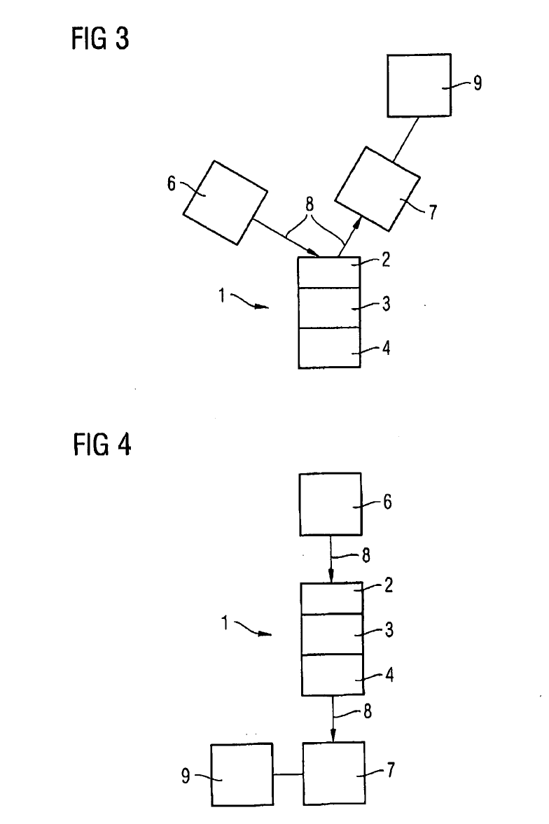

A schematic drawing of this arrangement is shown in FIG. 3 with an emitting device 6 that sends electromagnetic radiation 8 to a surface of the first electrode 2. The emitting device 6 may be a light emitting diode or a laser or any other illuminant source. Depending on the programming state of the programmable structure 1, more or less electromagnetic radiation 8 is reflected by the programmable structure 1. The reflected electromagnetic radiation 8 of the programmable structure 1 is received by a detecting device 7. The detecting device 7 generates an output signal depending on the intensity of the detected electromagnetic radiation. The detecting device forwards the output signal to a comparing unit 9. The comparing unit 9 comprises a memory in which a reference signal for a programmed state of the programmable structure is stored. The comparing unit 9 compares the output signal with a reference output signal. The reference output signal refers to a programmed state of the programmable structure 1. If the received output signal is equivalent or in a range of 10% of the reference signal, the comparing unit 9 detects a programmed state of the programmable structure 1. If the output signal is not equivalent to the reference signal and the value of the output signal deviates more than 10% of the reference signal, then the comparing unit 9 detects a non-programmed state of the programmable structure 1.

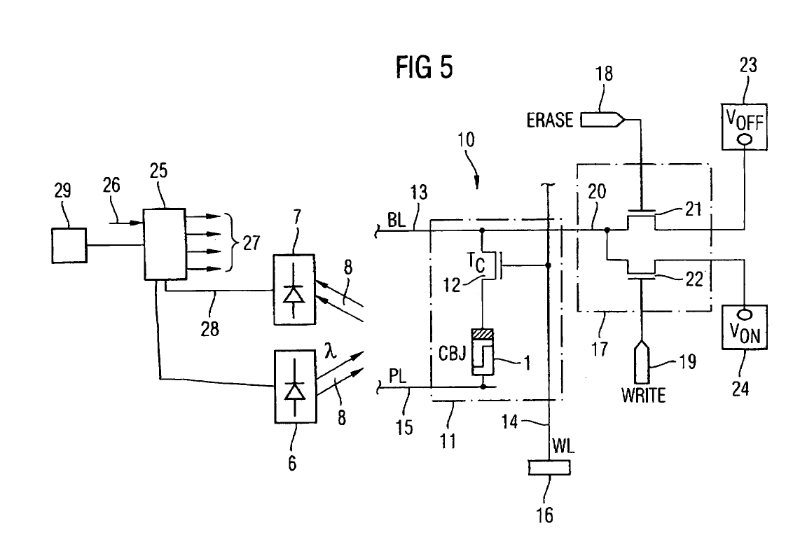

Another arrangement of the invention is shown in FIG. 4. FIG. 4 depicts an arrangement with an emitting device 6 that sends electromagnetic radiation 8 on a surface of the first electrode 2 of the programmable structure 1. The detecting device is arranged beneath the second electrode 4 of the programmable structure 1 receiving electromagnetic radiation 8 that is transmitted through the programmable structure 1. Depending on the programming state of the programmable structure 1, less or more electromagnetic radiation is transmitted through the programmable structure 1 to the detecting device 7. Therefore the detecting device 7 generates depending on the received electromagnetic radiation different output signals that are forwarded to the comparing unit 9. The comparing unit 9 comprises a memory in which a reference signal for a programmed state of the programmable structure is stored. The comparing unit 9 compares the received output signal of the detecting device with the stored reference signal. If the output signal equals to the reference signal or the value of the output signal is within a range of 10% of the reference signal, the comparing unit 9 detects a programmed state of the programmable structure 1. If the output signal is not equivalent to the reference signal and the value of the output signal deviates more the 10% of the reference signal, the comparing unit detects a non programmed state of the programmable structure.

The FIGS. 3 and 4 show that it is possible to detect a programmed state of the programmable structure 1 by using electromagnetic radiation in one embodiment using the reflected radiation and in the other embodiment using a transmitted radiation. A person skilled in the art might also use a combination of this two detecting methods.

FIG. 5 depicts parts of an electrical circuit 10 (for example, a memory device) comprising a memory cell 11 with a programmable structure 1 and a transistor 12. The transistor 12 is connected with drain and source between the first electrode 2 of the programmable structure 1 and a bit line 13, as illustrated. A gate of the transistor 12 is connected with a word line 14. The second electrode of the memory cell 11 is connected with a plate line 15. The word line 14 is connected with a word line controller 16. The word line controller 16 may be connected with several word lines that are not depicted in FIG. 5. Depending on a control command, the word line controller 16 selects one of the word lines and activates the selected word line 14 with a predetermined potential to switch the transistor 12 in a current state. The transistor 12 connects the bit line 13 with the first electrode 2 of the programmable structure 1.

The plate line 15 may be connected with a voltage source. Depending on the embodiment, the voltage source may also be operable to change the potential that is applied to the plate line 15. In a memory device a lot of bit lines 13 are arranged and each bit line 13 may be connected with several memory cells. All the memory cells may be connected with the second electrode to the plate line 15. Each word line may also be connected with a plurality of memory cells. A bit line controller 17 may be connected with a plurality of bit lines. Depending on a selecting signal, the bit line controller 17 selects one of the bit lines 13 and applies a write or an erase or no voltage to the selected bit line 13. The bit line controller 17 comprises an erase input 18 and a write input 19. The bit line 13 is connected with an output line 20 of the bit line controller 17. The output line 20 is connected with a second transistor 21 and a third transistor 22. The second transistor 21 is connected with the source and the drain terminal with a first voltage source 23. A gate of the second transistor 21 is connected with the erase input 18. The source and the drain of the third transistor 22 are connected with the output line 20 and a second voltage source 24. The first voltage source 23 supplies an erasing voltage that erases the programmed state of the programmable structure 1 if it is applied to the programmable structure 1. In example, the erasing voltage may be lower than −0.1 V. The second voltage source 24 supplies a writing voltage that writes a programming state in the programmable structure 1 if it is applied to the programmable structure 1. The writing voltage may be higher than 0.2 V. In this embodiment the voltage sources 23, 24 are used as a modifying device to change the program state of the programmable structure. Depending on the embodiment also other energy sources i. e. a light source or a heat source may be used as modifying devices to change the program state of the programmable structure 1.

Furthermore a controlling unit 25 is arranged that comprises a controlling input 26 for receiving controlling signals. The controlling unit 25 comprises controlling terminals 27 that are connected with the erase input 18 and the write input 19 of the bit line controller 17 and the word line controller 16. Additionally, an emitting device 6 and a detecting device 7 are arranged. The emitting device 6 is arranged in an optical connection to the memory cell 11 more precisely to the programmable structure 1 of the memory cell 11. The emitting device 6 sends electromagnetic radiation 8 that is depicted in the Figure as arrows to the programmable structure 1 of the memory cell 11. Additionally, the detecting device 7 is disposed in an optical connection to the programmable structure 1 of the memory cell 11. The electromagnetic radiation that is received by the programmable structure 1 of the memory cell 11 is reflected to the detecting device 7. The detecting device 7 detects the received electromagnetic radiation 8 and transmits an electrical output signal by a sensing line 28 to the controlling unit 25. Depending on the programmed state of the programmable structure 1 as explained above, the detecting device 7 detects different electromagnetic radiations. Depending on the different electromagnetic radiations, the detecting device 7 generates different output signals that are delivered to the controlling unit 25. The controlling unit 25 is connected with a reference memory 29 in which reference signals for a programmed and a not programmed state of the memory cell are stored for the output signals of the detecting device 7. The controlling unit 25 compares the output signal that is delivered by the detecting device 7 with the stored reference signals. Depending on the comparison, the controlling unit 25 detects a programmed or a not programmed state of the memory cell 11. Using this information, a stored data may be read out from the memory cell 11.

If the controlling unit 25 receives an instruction to program the memory cell 11, it transmits a high voltage signal by the controlling outputs 27 to the write input 19 of the bit line controller. Therefore a high voltage is put by the bit line controller 17 on the bit line 13. Simultaneously, no voltage signal is delivered to the erase input 18 of the bit line controller 17. Additionally, the controlling unit 25 sends an instruction signal to the word line controller 16 to select the word line 14 and activate the word line 14. Additionally, the word line controller 16 activates the word line 14, thus switching on the transistor 12. This results in a high voltage that is applied on the first electrode 2 of the programmable structure 1 of the memory cell 11. Because the second electrode 4 is connected with the plate line 15 that is connected with a low voltage, a programming voltage higher than the threshold voltage is applied to the programmable structure 1. Therefore ions are solved from the first electrode 2 and dissolved in the ion conductor 3 of the programmable structure 1. This changes the electromagnetic property of the programmable structure 1 referring to transmitting and/or reflecting electromagnetic radiation through or by the programmable structure.

In one embodiment, the reflectivity of the programmable structure 1 is lowered by programming the programmable structure 1.

Depending on the used materials, it may be possible that the reflectivity of the programmable structure 1 is increased by programming the programmable structure 1.

If the controlling unit 25 receives an erasing instruction by the controlling input 26, the controlling unit 25 puts a high voltage on the erase input 18 that switches the second transistor 21 in a current state, connecting the first voltage source 23 with the bit line 13. Additionally, the controlling unit 25 puts a low voltage on the write input 19 that switches the third transistor 22 in a non-current state. Additionally, the controlling unit 25 sends a controlling signal to the word line controller 16 to select the word line 14 and activate the word line 14. Therefore the bit line 13 is connected by the transistor 12 with the programmable structure 1 of the memory cell 11. Because of the low voltage of the first voltage source 23, the programmable structure 1 is reprogrammed. That means that the ions of the first electrode are dissolved in the ion conductor layer 3 and redrawn to the first electrode 2 and the programmable structure 1 has the same electromagnetic property as prior before the programming.

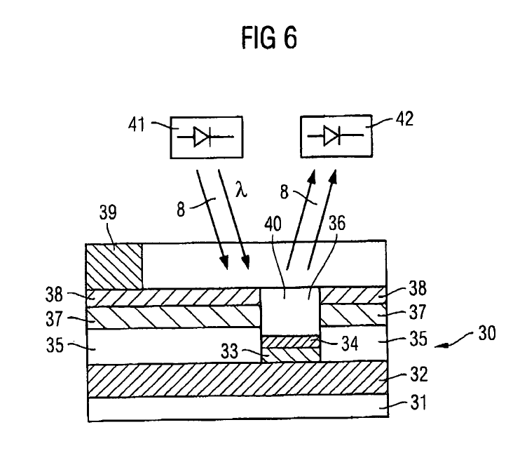

FIG. 6 depicts an embodiment of a second programmable structure 30 comprising a substrate 31, a bottom electrode 32 and a dielectric layer 35 with a recess 36. The dielectric layer 35 may be constituted by any dielectric material that is electrically insulating. The recess 36 reaches down to the bottom electrode 32 and is filled partially at the bottom with a second ion conductor layer 33. On the second ion conductor layer 33 a top electrode layer 34 is arranged. On the surface of the dielectric layer 35 a further ion conductor layer 37 is disposed that is covered with a further top electrode layer 38. On the further top electrode 38 a second bit line 39 is disposed. In this Figure there is not shown the transistor 12 for selecting by a word line the second programmable structure 30 that is constituted by the bottom electrode 2, the second ion conductor layer 33 and the top electrode layer 34. The thickness of the second ion conductor layer 33 is smaller than the thickness of the further ion conductor layer 37. Furthermore, the thickness of the top electrode layer 34 is smaller than the thickness of the further top electrode 38. The smaller thickness in the recess 36 is generated by the depositing process i.e. by a chemical vapor deposition method which results in a smaller thickness within the recess 36. The recess 36 may be covered with a filling 40 that transmits electromagnetic radiation. In the shown embodiment, a second emitting device 41 and a second detecting device 42 are disposed. The second emitting device 41 sends electromagnetic radiation 8 to the recess 36 on the top electrode 34. Additionally, reflected radiation of the second programmable structure 30 is reflected to the second detecting device 42.

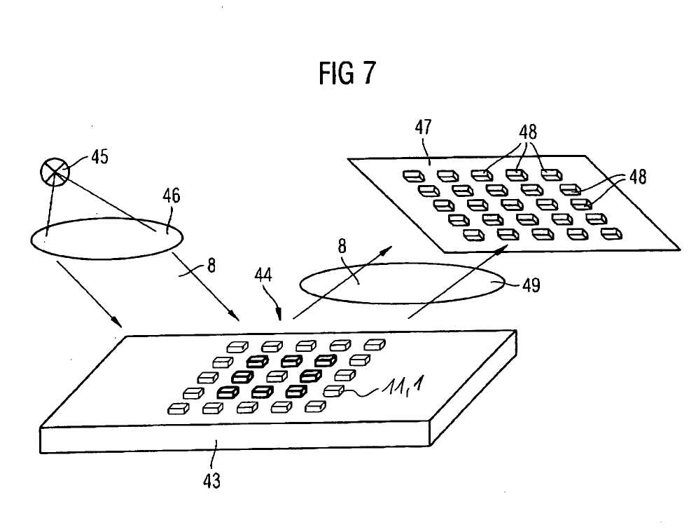

FIG. 7 depicts another embodiment of the invention with a further substrate 43 comprising an array 44 of programmable structures 1. The programmable structures of the array are disposed on the surface of the second substrate 43. The programmable structures 1 of the array 44 have rectangular shapes and the programmable structures are disposed in a rectangular pattern with equidistant distances between the programmable structures. On the second substrate 43 is also disposed, but not shown the electrical circuit 10 for programming and erasing the programmable structures 1. The programmable structures 1 are connected with transistors to bit lines and disposed in rows and lines constituting memory cells. The memory elements of the rows are connected with one word line and the memory elements of one line are connected with one bit line according the structure of FIG. 5. Above the second substrate 43 a light source 45 is arranged that sends electromagnetic radiation through an optical lens 46 to the array 44. The memory elements of the array 44 reflect electromagnetic radiation to a third detecting device 47. The third detecting device 47 comprises a second array of detecting units 48. Between the second substrate 43 and the third detecting device 47 a second optical lens arrangement 49 is disposed to guide the reflected electromagnetic radiation 8 that is reflected by one memory element directly to one detecting unit 48. Therefore it is possible to detect by the third detecting device 47 an array of memory cells using one light source and one detecting device. Each one of the detecting units 48 of the third detecting device 47 detects the state of the assigned memory cell. Therefore it is possible, to read out in one process in parallel a lot of memory cells.

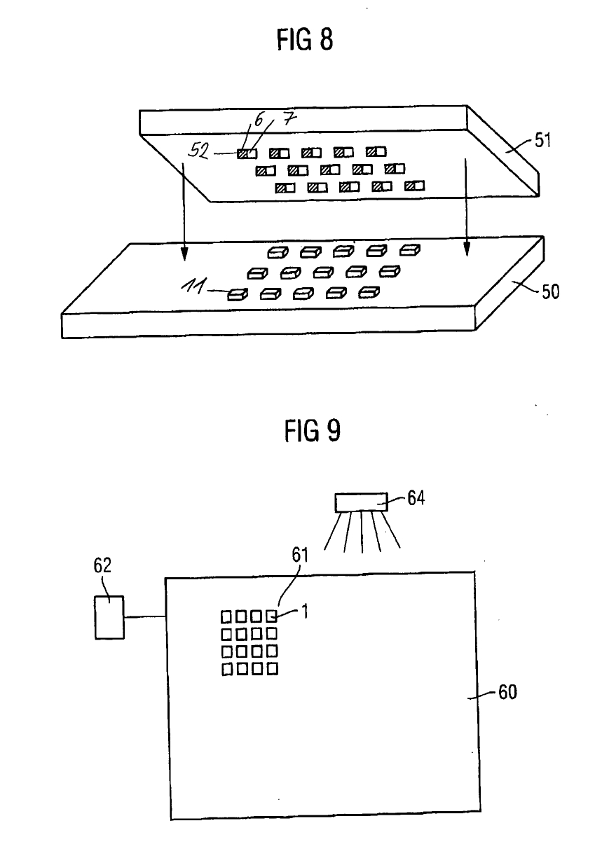

In a further embodiment, as shown in FIG. 8, a memory, i. e. a DRAM may be constituted by a third and a fourth substrate 50, 51. On the third substrate 50 an array of memory cells is disposed and the electrical circuit 10 according to FIG. 5 for erasing and writing a programmed state in the memory cells is disposed in the third substrate 50, without being shown.

On the fourth substrate 51 an array of combined units 52 each comprising an emitting device 6 and a detecting device 7. In this embodiment the emitting device 6 may be a light emitting diode and the detecting device 7 may be a photo diode. The combined units 52 of the fourth substrate 51 are arranged in the same pattern as the memory cells on the third substrate 50. Therefore it is possible to put the third and the fourth substrate 50, 51 with a face-to-face orientation together and put an combined unit directly on a memory cell. Therefore, for each memory cell, an combined unit is disposed for sending and detecting an electromagnetic radiation of one dedicated memory cell. The controlling unit 25 may be disposed on the third or on the fourth substrate 50, 51. The third and the fourth substrate 50, 51 may be connected by a bonding or a flip chip technique fabricated by a multi chip module arrangement. This has the advantage that the third and the fourth substrate 50, 51 may be processed until the connecting in different processing lines. Therefore might be a greater flexibility for using the appropriate processes for fabricating the combined units 52 on the one substrate and the memory cells on the other substrate independently.

Depending on the used embodiment, there might also be an optical line for guiding the electromagnetic radiation from the light source to the memory cell. Furthermore there might also be optical lines for guiding the reflected or the transmitted electromagnetic radiation from the memory cells to the detecting units.

Additionally, there might be an optical transmissible interlayer between the third and the fourth substrate 50, 51 between the memory cells and the emitting/detecting units 52. Preferably the interlayer might also have adhesive properties to hold the third and the fourth substrate 50, 51 together. The substrates may be made of silicon or any other semiconductor material.

FIG. 9 depicts a schematic view of a display 60 comprising an array 61 of programmable structures 1 that are disposed in rows and columns. The programmable structure 1 comprises a first electrode, a second electrode and an ion conductor layer. The first electrode may comprise solvable ions and may be connected in one embodiment to a high potential, for example, during a programmable operation. The second electrode may be connected in this embodiment to a ground potential that is lower than the high potential. In this embodiment, the first electrode functions as an anode and the second electrode functions as a cathode. The function and the structure of the programmable structure is the same as explained referring to FIG. 1.

Each of the programmable structures 1 is controllable by a controlling unit 62 that is operable to select one of the programmable structure 1 individually and to change the reflectivity of the programmable structure 1 as explained with FIG. 5. Depending on the programmed state, the programmable structures 1 may have different transmission properties for electromagnetic radiation in the visible range. In this embodiment, the display 60 may be irradiated with electromagnetic radiation by a light source 64 in the visible range from the backside. Depending on the programmed states of the programmable structures 1 pictures are visible from a front of the display panel. Each of the programmable structures 1 may constitute a pixel of the display.

Depending on the embodiment, the display may also display a color picture, whereby each of the pixel is operable to transmit a part of the spectrum of the visible light of the light source 64.

In another embodiment the display 60 is irradiated with visible light from the front and the programmable structures 1 are operable to change reflectivity of visible light by changing the programmed state of the programmable structures 1. Therefore a picture may be visible from the front of the display as a result of different brightness of the programmable structure.

While the foregoing is directed to embodiments of the present invention, other and further embodiments of the invention may be devised without departing from the basic scope thereof, and the scope thereof is determined by the claims that follow.

What is claimed is:

1. A programmable structure, comprising:
an ion conductor layer arranged between a first electrode comprising dissolvable ions and a second electrode;
a modifying device coupled to the ion conductor layer, wherein the modifying device is configured to change an electromagnetic property of the ion conductor layer;
an emitting device configured to send a first electromagnetic radiation to the ion conductor layer; and
a detecting device configured to receive a second electromagnetic radiation from the ion conductor layer, the second electromagnetic radiation being related to the first electromagnetic radiation sent to the ion conductor layer and being indicative of a state of the programmable structure.

2. The programmable structure of claim 1, wherein the modifying device is configured to apply a first signal greater than a threshold signal value to dissolve ions from the first electrode and transfer the dissolved ions from the first electrode into the ion conductor layer, thereby changing the electromagnetic property of the ion conductor layer.

3. The programmable structure of claim 1, wherein the modifying device is configured to apply an erase signal to dissolve ions in the ion conductor layer and transfer dissolved ions in the ion conductor layer into the first electrode, thereby changing the electromagnetic property of the ion conductor layer.

4. The programmable structure of claim 1, wherein the modifying device is a voltage source wherein a first terminal of the voltage source is connected to the first electrode and a second terminal of the voltage source is connected to the second electrode and the voltage source is configured to:
apply a voltage higher than a threshold voltage between the first electrode and the second electrode to dissolve ions from the first electrode and transfer the dissolved ions into the ion conductor layer, thereby changing the electromagnetic property of the ion conductor layer; and
apply an erase voltage between the first electrode and the second electrode to dissolve ions in the ion conductor layer and transfer the dissolved ions into the first electrode, thereby changing the electromagnetic property of the ion conductor layer.

5. The programmable structure of claim 4, wherein the erase voltage is a negative voltage.

6. The programmable structure of claim 1, wherein the programmable structure is a memory cell wherein the electromagnetic property of the ion conductor layer represents data stored in the memory cell.

7. The programmable structure of claim 1, wherein the emitting device sends the first electromagnetic radiation to the ion conductor layer and the ion conductor layer reflects at least partially the first electromagnetic radiation to the detecting device, wherein the at least partially reflected first electromagnetic radiation is the second electromagnetic radiation.

8. The programmable structure of claim 1, further comprising a comparing unit, wherein the comparing unit is configured to receive a signal generated by the detecting unit and determine whether the memory cell is in a first programmed state, wherein the signal received by the comparing unit is generated by the detecting unit in response to receiving the second electromagnetic radiation.

9. The programmable structure of claim 1, wherein the ion conductor layer is arranged on a first substrate and the emitting and detecting devices are arranged on a second substrate, wherein the first substrate and the second substrate are arranged face to face.

10. Memory, comprising:
at least one memory cell, wherein the memory cell comprises:
an ion conductor layer arranged between a first electrode comprising dissolvable ions and a second electrode; and
a modifying device coupled to the ion conductor layer, wherein the modifying device is configured to change an electromagnetic property of the ion conductor layer; and
associated with each of the at least one memory cells:
an emitting device configured to send a first electromagnetic radiation to the ion conductor layer;
a detecting device configured to receive a second electromagnetic radiation from the ion conductor layer and generate a signal in response to receiving the second electromagnetic radiation; and
a comparing unit configured to receive the signal and determine whether the memory cell is in a first programmed state.

11. The memory of claim 10, wherein the at least one memory cells are arranged as an array on a first substrate and an array of each of the emitting device, the detecting device, and the comparing unit associated with each memory cell are arranged on a second substrate, wherein the first substrate and the second substrate are arranged face to face.

12. The memory of claim 10, wherein the modifying device is configured to store data in the memory cell by applying a signal to the memory cell, wherein the signal dissolves the ions and transfer the ions between the first electrode and the ion conductor layer, thereby changing the electromagnetic property of the ion conductor layer, wherein the electromagnetic property of the ion conductor layer determines the data stored in the memory cell.

13. A display comprising a plurality of programmable structures, wherein the programmable structure comprises:
an ion conductor layer arranged between a first electrode comprising dissolvable ions and a second electrode; and
a modifying device coupled to the ion conductor layer, wherein the modifying device is configured to change an electromagnetic property of the ion conductor layer; and
an emitting device configured to send a first electromagnetic radiation to the ion conductor layer.

14. The display of claim 13, further comprising a plurality of pixels, wherein a programmable structure is associated with each pixel.

15. The display of claim 14, wherein each pixel is irradiated by a second electromagnetic radiation wherein the second electromagnetic radiation is generated by reflecting the first electromagnetic radiation from the ion conductor layer.

16. The display of claim 13, wherein the modifying device is configured to apply a first signal greater than a threshold signal value to dissolve ions from the first electrode and transfer the dissolved ions into the ion conductor layer, thereby changing the electromagnetic property of the ion conductor layer.

17. The display of claim 16, wherein the value of the first signal determines the electromagnetic property of the ion conductor layer, the electromagnetic property comprising the electromagnetic reflectivity of the ion layer.

18. The display of claim 17, the electromagnetic reflectivity of the ion conductor layer determines the optical information displayed on the display.

19. A method for accessing data in a memory cell comprising an ion conductor layer arranged between a first electrode comprising dissolvable ions and a second electrode, comprising:
storing data in the memory cell by applying a signal to the memory cell, wherein the signal dissolves the ions and transfer the ions between the first electrode and the ion conductor layer, thereby changing the electromagnetic property of the ion conductor layer; and
reading the data by:
sending a first electromagnetic radiation to the ion conductor layer;
receiving a second electromagnetic radiation from the ion conductor layer, wherein the second electromagnetic radiation comprises the first electromagnetic radiation that is partially reflected from the memory cell; and
determining the data stored in the memory cell based on the second electromagnetic radiation received.

20. The method of claim 19, wherein determining the data stored in the memory cell comprises determining whether the intensity of the second electromagnetic radiation is greater than a predetermined intensity value.
